(19) United States
(12) Patent Application Publication
(10) Pub. No.: US 2014/0190412 A1
(43) Pub. Date: Jul. 10, 2014

(54) APPARATUS FOR FABRICATING INGOT

(71) Applicants: Bum Sup Kim, Seoul (KR); Dong Geun Shin, Seoul (KR)

(72) Inventors: Bum Sup Kim, Seoul (KR); Dong Geun Shin, Seoul (KR)

(73) Assignee: LG INNOTEK CO., LTD., Seoul (KR)

(21) Appl. No.: 14/122,101

(22) PCT Filed: May 24, 2012
(86) PCT No.: PCT/KR2012/004096

§ 371 Date: Feb. 28, 2014

(30) Foreign Application Priority Data
May 24, 2011 (KR) 10-2011-0049182

(51) Int. Cl. C30B 23/00

(52) U.S. Cl. CPC C30B 23/005
USPC 118/726

(57) ABSTRACT

Disclosed is an apparatus for fabricating an ingot. The apparatus includes a crucible to receive a raw material, and a filter part to allow a specific component in the crucible to selectively pass through the filter part. The raw material includes silicon and carbon.

### TECHNICAL FIELD

The disclosure relates to an apparatus for fabricating an ingot.

### BACKGROUND ART

In general, materials are very important factors to determine the property and the performance of final products in the electric, electronic and mechanical industrial fields.

SiC represents the superior thermal stability and superior oxidation-resistance property. In addition, the SiC has the superior thermal conductivity of about 4.6 W/Cm° C., so the SiC can be used for fabricating a large-size substrate having a diameter of about 2 inches or above. In particular, the single crystal growth technology for the SiC is very stable actually, so the SiC has been extensively used in the industrial field as a material for a substrate.

In order to grow the single crystal for SiC, a seeded growth sublimation scheme has been suggested. In this case, after putting a raw material in a crucible, and a SiC single crystal serving as a seed is provided on the raw material. Temperature gradient is formed between the raw material and the seed, so that the raw material in the crucible is dispersed to the seed, and re-crystallized to grow a single crystal.

When the SiC single crystal is grown, SiC powders are typically used as a raw material. When the SiC powders are used as a raw material, two much time is spent to synthesize the SiC powder. In addition, when the SiC powders are filled in the crucible, impurities are introduced to exert an influence on the quality of the single crystal.

### DISCLOSURE OF INVENTION

### Technical Problem

The embodiment can grow a high-quality single crystal.

### Solution to Problem

According to the embodiment, there is provided an apparatus for fabricating an ingot. The apparatus comprises a crucible to receive a raw material therein, and the raw material includes a compound containing silicon and carbon.

### Advantageous Effects of Invention

According to the apparatus for fabricating the ingot, the polymer containing Si and C may be used as a raw material to grow a single crystal. In detail, the raw material may include polycarbosilane. The fabricating time can be reduced, and the fabricating process can be simplified by using the polycarbosilane as a raw material instead of existing SiC powder. This is because a synthesizing process to prepare the existing SiC power can be omitted. In other words, SiC raw material can be simultaneously synthesized and grown by using the polycarbosilane as a raw material. Accordingly, the raw material can be prevented from being contaminated. Therefore, impurities can be prevented from being introduced into the single crystal, so that a high-quality single crystal can be grown.

Thereafter, the raw material can be fully consumed by using the polycarbosilane as the raw material. Accordingly, the quantity of single crystals created with respect to introduced raw material in the process can be quantified. In addition, after the single crystal has been produced, the raw material can be fully consumed, thereby preventing an inconvenient work of recovering and reusing the raw material in the crucible.

The apparatus for fabricating the ingot according to the embodiment includes the filter part. The filter part selectively allows a specific component to pass through the filter part. In detail, material sublimated from the raw material includes SiC₂, Si₂C, Si, and C impurities, and the filter part can adsorb the C impurities. In other words, the C impurities derived from the raw material can be prevented from participating in the growth procedure of the single crystal. If the C impurities are moved to the single crystal, the single crystal may be defected. Accordingly, the filter part can prevent the single crystal from being defected.

### BRIEF DESCRIPTION OF DRAWINGS

FIG. 1 is a sectional view showing an apparatus for fabricating an ingot; and

FIG. 2 is an enlarged sectional view showing a part A of FIG. 1.

### MODE FOR THE INVENTION

In the description of embodiments, it will be understood that when a layer (or film), region, pattern or structure is referred to as being ‘on’ or ‘under’ another layer (or film), region, pad or pattern, the terminology of ‘on’ and ‘under’ includes both the meanings of ‘directly’ and ‘indirectly’. Further, the reference about ‘on’ and ‘under’ each layer will be made on the basis of drawings.

The thickness and size of each layer (film), region, pattern, or structure shown in the drawings may be exaggerated, omitted or schematically drawn for the purpose of convenience or clarity. In addition, the size of each layer (film), region, pattern, or structure does not utterly reflect an actual size.

Hereinafter, the embodiment of the present invention will be described in detail with reference to accompanying drawings.

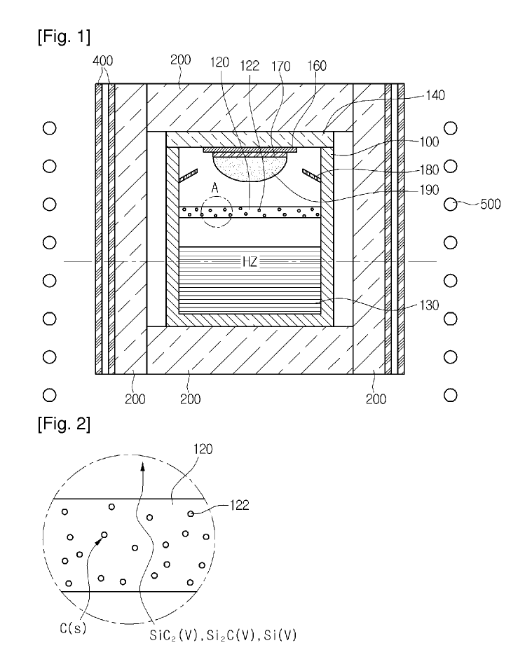

Hereinafter, an apparatus for fabricating an ingot according to the embodiment will be described in detail with reference to FIGS. 1 and 2. FIG. 1 is a sectional view showing the apparatus for fabricating the ingot according to the embodiment. FIG. 2 is an enlarged sectional view showing a part A of FIG. 1.

Referring to FIG. 1, the apparatus for fabricating the ingot includes a crucible 100, a raw material 130, a filter part 120, a top cover 140, a seed holder 170, a focusing tube 180, an adiabatic material 200, a quartz tube 400 and a heat induction part 500.

The crucible 100 receives source materials 130 therein.

The crucible 100 has a cylindrical shape to receive the source materials 130.

The crucible 100 may include a material having the melting point higher than the sublimation temperature of the SiC.

For example, the crucible 100 can be manufactured by using graphite.

In addition, the crucible 100 can be manufactured by coating a material having the melting point higher than the sublimation temperature of the SiC on the graphite. Preferably, a material, which is chemically inert with respect to silicon and hydrogen at the growth temperature for the SiC single crystal, is used as the material coated on the graphite. For instance, the material may include metal carbide or nitride carbide. In particular, a mixture including at least two of Ta, Hf, Nb, Zr, W and V and carbide including carbon can be coated on the graphite. Further, a mixture including at least two of Ta, Hf, Nb, Zr, W and V and nitride including nitrogen can be coated on the graphite.

The source materials 130 may include silicon and carbon. In detail, the source materials 130 may a compound containing silicon (Si), carbon (C), oxygen (O), and hydrogen (H). In more detail, the raw material 130 may include polymer containing Si and C. For example, the raw material 130 may include polycarbosilane.

The polycarbosilane is a kind of polysilane. The polycarbosilane is polymer having a backbone chain of Si and C. The polycarbosilane is pre-ceramic raw material used as raw material for a high performance fiber such as SiC fiber having a microdiameter which is used for an ultra high temperature. Since the polycarbosilane, which is polymer, can be easily processed in various forms, the polycarbonsilane is variously applicable in a fibrous form, a film-like form, a porous form, a coating form, and the like. According to the apparatus for fabricating the ingot according to the present embodiment, various kinds of polycarbosilanes are used as the raw material 130.

The polycarbosilane may be prepared through various schemes.

The fibrous polycarbosilane may be stacked into the crucible 100.

If the polycarbosilane is maintained at the temperature of about 1200° C. to 1500° C. for several hours, the polycarbosilane is subject to organic-inorganic transformation through thermal-decomposition. Thereafter, the polycarbosilane is converted into SiC. If a temperature is raised to the growth temperature of a single crystal of the SiC, impurities such as SiC₂, Si₂C, Si and C are derived from the SiC.

The SiC₂, Si₂C and Si are sublimated and moved to the seed 170 so that a single crystal 190 can be grown.

The fabricating time can be reduced, and the fabricating process can be simplified by using the polycarbosilane as a raw material instead of existing SiC powder. This is because a synthesizing process to prepare the existing SiC power can be omitted. In other words, SiC raw material is simultaneously synthesized and grown by using the polycarbosilane as a raw material.

In addition, after synthesizing the SiC powder, when the SiC powder is filled in the crucible, the raw material can be prevented from being contaminated. Therefore, impurities can be prevented from being introduced into the single crystal 190, so that a high-quality single crystal can be grown.

Thereafter, the raw material 130 can be fully consumed by using the polycarbosilane as the raw material 130. Accordingly, the quantity of single crystals created with respect to introduced raw material in the process can be quantified. In addition, after the single crystal 190 has been produced, the raw material can be fully consumed, thereby preventing an inconvenient work of recovering and reusing the raw material in the crucible.

Thereafter, the filter part 120 may be provided in the crucible. In detail, the filter part 120 may be placed above the raw material 130.

The filter part 120 may allow a specific component to selectively pass through the filter part 120. In detail, the filter part 120 may adsorb C impurities. In other words, C impurities derived from the raw material 130 can be prevented from participating in the growth procedure of the single crystal 190. If the C impurities are moved to the single crystal 190, the single crystal 190 may be defected.

The filter part 120 may have a thickness T in a range of 1 mm to 10 cm. The thickness T of the filter part 120 may be selected according to the size and the scale of the crucible 100. If the filter part 120 has a thickness T of 1 mm or less, the thickness T is excessively thin, so that the filter part 120 may not adsorb the C impurities. If the filter part 120 has the thickness T exceeding 10 cm, the thickness T is excessively thick so that the transmission speed of materials other than the C impurities may be reduced. In other words, the transmission speed of SiC₂, Si₂C and Si used to grow the single crystal 190 may be lowered. Accordingly, the growth speed of the single crystal 190 may be lowered.

The filter part 120 may have a porous structure. In other words, the filter part 120 may have a plurality of pores 122. Referring to FIG. 2, the pores 122 can adsorb C impurities having a very small size and contaminants. In addition, the filter part 120 may allow SiC₂, Si₂C and Si to pass through the filter part 120 and move SiC₂, Si₂C and Si to the seed 170.

The filter part 120 may include a membrane. In detail, the filter part 120 may include a carbon-based membrane.

The carbon-based membrane may be prepared by compression-molding and calcining graphite powder. The carbon-based membrane represents superior durability, a superior penetration property, and superior filterability. Therefore, when the filter part 120 includes the carbon-based membrane, the high-quality single crystal 190 can be prepared.

However, the embodiment is not limited thereto, so that the filter part 120 may include various materials representing superior durability, a superior penetration property, and superior filterability.

A top cover 140 is positioned at the upper portion of the crucible 100. The top cover 140 can seal the crucible 100. In detail, the top cover 140 may include graphite.

The seed holder 160 is located at a lower end of the top cover 140. The seed holder 160 may fix the seed 170. The seed holder 160 may include high-density graphite.

The seed 170 is attached to the seed holder 160. The seed 170 is attached to the seed holder 160, so that the single crystal 190 can be prevented from being grown to the upper cover 140. However, the embodiment is not limited thereto, and the seed 170 may directly make contact with the upper cover 140.

The focusing tube 180 is located in the crucible 100. The focusing tube 180 may be located at a region where the single crystal is grown. The focusing tube 180 narrows a path of sublimated SiC gas to concentrate the sublimated SiC gas onto the seed 190. Thus, the growth rate of the single crystal may be improved.

The adiabatic material 200 surrounds the crucible 100. The adiabatic material 200 keeps the temperature of the crucible 100 to the level of the crystal growth temperature. Since the crystal growth temperature of the SiC is high, graphite felt may be used as the adiabatic material. In detail, the adiabatic material 200 can be prepared by compressing graphite fiber in the form of a cylinder having a predetermined thickness. In addition, the adiabatic material 200 may be prepared as a plurality of layers surrounding the crucible 100.

The quartz tube 400 is positioned at an outer peripheral surface of the crucible 100.

The quartz tube 400 is fitted around the outer peripheral surface of the crucible 100. The quartz tube 400 may block heat transferred to a single crystal growth apparatus from the heat induction part 500. The quartz tube 400 is a hollow tube and cooling water may circulate through an inner space of the quartz tube 400.

The heat induction part 500 is positioned outside the crucible 100. For instance, the heat induction part 500 is an RF induction coil. As RF current is applied to the RF induction coil, the crucible 100 can be heated. That is, the source materials contained in the crucible 100 can be heated to the desired temperature.

The center area of the heat induction part 500 is located below the center area of the crucible 100. Thus, the temperature gradient may occur at the upper and lower portions of the crucible 100. That is, the center area (hot zone; HZ) of the heat induction part 500 is located relatively lower than the center area of the crucible 100, so the temperature of the lower portion of the crucible 100 may be higher than the temperature of the upper portion of the crucible 100 on the basis of the hot zone HZ. In addition, the temperature may rise from the center of the crucible 100 to the outer peripheral portion of the crucible 100. Due to the temperature gradient, the SiC source materials may be sublimated so that the sublimated SiC gas moves to the surface of the seed 170 having the relatively low temperature. Thus, the SiC gas is re-crystallized, so the SiC single crystal 190 is grown.

Any reference in this specification to “one embodiment”, “an embodiment”, “example embodiment”, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for fabricating an ingot, the apparatus comprising:
a crucible to receive a raw material; and
a filter part to allow a specific component in the crucible to selectively pass through the filter part, wherein the raw material includes silicon and carbon.

2. The apparatus of claim 1, wherein the raw material includes polycarbosilane.

3. The apparatus of claim 1, wherein the filter part adsorbs carbon impurities.

4. The apparatus of claim 1, wherein the filter part includes a membrane.

5. The apparatus of claim 1, wherein the filter part is placed on the raw material.

6. The apparatus of claim 1, wherein the filter part has a thickness in a range of 1 mm to 10 cm.

7. The apparatus of claim 1, wherein the filter part has a porous structure.

8. The apparatus of claim 4, wherein the membrane includes a carbonbased membrane.
